(19) United States
(12) Patent Application Publication
(10) Pub. No.: US 2026/0107600 A1
(43) Pub. Date: Apr. 16, 2026

(54) ELECTRONIC DEVICE HAVING SIGNAL TRANSMISSION FEATURE

(71) Applicant: Taiwan Semiconductor Manufacturing Company, Ltd., Hsinchu (TW)

(72) Inventors: Chia Chen Lee, Taipei City (TW); Chia-Tien Wu, Taichung City (TW); Ken-Hsien HSIEH, Taipei City (TW); Chi-Yu Lu, New Taipei City (TW); Yi-Yi Chen, Keelung City (TW)

(73) Assignee: Taiwan Semiconductor Manufacturing Company, Ltd., Hsinchu (TW)

(21) Appl. No.: 18/912,566

(22) Filed: Oct. 10, 2024

(51) Int. Cl. H01L 27/146

(52) U.S. Cl. CPC H10F 39/811; H10F 39/809

(57) ABSTRACT

An electronic device including a first electronic element, a second electronic element, a first signal track, and a second signal track is provided. The second electronic element is different from the first electronic element. The first signal track is electrically connected to the first electronic element. The second signal track is electrically connected to the second electronic element and electrically separated from the first signal track. A width of the second signal track is substantially 8˜100 nm. The first signal track has a larger cross-sectional area than the second signal track.

### BACKGROUND

The semiconductor integrated circuit (IC) industry has experienced a fast-paced growth. Technological advances in IC materials and design have produced multiple generations of ICs where each generation has smaller and more complex circuits than the previous generation. However, with chip scale shrinkage, resistance of a circuit may be increased that consume the benefit of density boost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a portion of a circuit diagram of an electronic device of an embodiment of the disclosure.

FIG. 2 illustrates a portion of a layout design flow of an embodiment of the disclosure.

FIGS. 3A and 3B illustrate a portion of layout design diagrams of an embodiment of the disclosure.

FIG. 4 illustrates a top view of a portion of an electronic device of an embodiment of the disclosure.

FIG. 5 illustrates a top view of a portion of an electronic device of an embodiment of the disclosure.

FIG. 6 illustrates a cross-sectional view of a portion of an electronic device of an embodiment of the disclosure.

FIG. 7 illustrates a top view of a portion of another electronic device of an embodiment of the disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

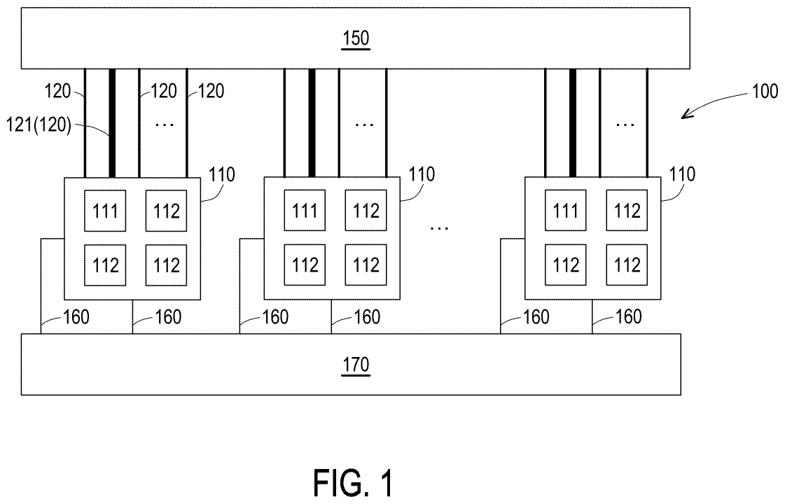

FIG. 1 illustrates a portion of a circuit diagram of an electronic device 100 of an embodiment of the disclosure.

Referring to FIG. 1, an electronic device 100 includes at least one electronic element cell 110. Three electronic element cells 110 are exemplarily shown in FIG. 1, but the disclosure is not limited thereto. If the number of electronic element cells 110 is multiple, the plurality of electronic element cells 110 could be arranged in an appropriate manner, such as but not limited to a row, a column, an array, or a ring.

The electronic element cell 110 could be electrically connected to a power supply unit 170 by one or more power circuits 160. The power supply unit 170 may be an internal unit included in the electronic device 100, and/or an external unit that does not integrated in the electronic device 100. In some embodiments, the electronic device 100 may be an integrated circuit (IC) chip, and the power supply unit 170 may be an electronic element integrated therein and include active electronic elements (or further including corresponding passive electronic elements or appropriate circuits) to perform voltage regulation, rectification, shunting, switching, frequency modulation, phase change, other appropriate power regulation or power management on the electric energy input thereto. In some embodiments, the electronic device 100 may be an electronic package, and the power supply unit 170 may be a power management IC (PMIC) packaged within the electronic package. In some embodiments, the electronic device 100 may include one or more conductive terminals, and an external power supply unit 170 (e.g., a battery, a charger) could be electrically connected to one or more corresponding conductive terminals. In some embodiments, the power supply unit 170 may be a combination or integration abovementioned.

The electronic element cell 110 could be electrically connected to a signal processing unit 150 by a plurality signal circuits 120. The signal processing unit 150 may be an internal unit included in the electronic device 100, and/or an external unit that does not integrated in the electronic device 100. In some embodiments, the electronic device 100 may be an integrated circuit (IC) chip, and the signal processing unit 150 may be an electronic element integrated therein and include active electronic elements (or further including corresponding passive electronic elements or appropriate circuits), for performing logic operations or signal processing (e.g., judging or determining input signals) and/or signal transmission (e.g., sending drive signal or trigger signal). In some embodiments, the electronic device 100 may be an electronic package, and the signal processing unit 150 may be a Central Process Unit (CPU) dies, a Graphic Process Unit (GPU) dies, a Tensor Processing Unit (TPU), a Field-Programmable Gate Array (FPGA) packaged within the electronic package. In some embodiments, the electronic device 100 may include one or more conductive terminals, and a signal processing unit 150 could be electrically connected to one or more corresponding conductive terminals. In some embodiments, the signal processing unit 150 may be a combination or integration abovementioned.

One of the plurality signal circuits 120 corresponding to a single electronic element cell 110 may be referred to as a critical signal circuit 121 owing that the critical signal circuit 121 is provided to transmit certain critical signals that require higher transmission quality. For example, if the overall resistance value of a signal circuit is too high, excessive signal decay may occur during signal transmission, resulting in incorrect judgment or determination for the critical signals by the signal processing unit 150.

In an embodiment, among all signal circuits 120 between the signal processing unit 150 and the single electronic element cell 110, the critical signal circuit 121 has the lowest resistance value. The aforementioned resistance value could be defined or measured as the overall resistance between the two opposite endpoints corresponding to the signal processing unit 150 and the single electronic element cell 110 for a single signal circuit 120.

In an embodiment, the signal transmitted by the critical signal circuit 121 is an analog signal. Among methods of transmitting electrical signals through conductors, analog signals are more sensitive to electricity than digital signals.

In an embodiment, a resistance value of a corresponding circuit (e.g., the critical signal circuit 121) could be reduced by using a conductive material with lower resistivity, increasing a physical cross-sectional area (e.g., increasing a cross-sectional area perpendicular to the current flow direction), and/or increasing an equivalent cross-sectional area (e.g., increasing parallel current paths).

In an IC chip (one implemental example of an electronic device 100), conductive material and/or thickness for the conductive portions (e.g., lines or vias) of the same layer (e.g., M0 layer, M1 layer, M3 layer, M4 layer and so on, or V0 layer, V1 layer, V3 layer, V4 layer and so on) is substantially the same. As such, in an IC chip (one implemental example of an electronic device 100), among one group of conductive portions (that is, all conductive portions electrically connected to the same signal processing unit 150 and the single electronic element cell 110 could be referred as the same group) on the same layer, the conductive line serving as the critical signal circuit 121 has a maximum physical width or a maximum equivalent width.

In an embodiment, an electronic element cell 110 includes one or more electronic elements. For example, the electronic element cell 110 includes a plurality of electronic elements 111, 112. The electronic element 111 may be referred as a first electronic element, the electronic element 112 may be referred as a second electronic element. Electronic elements 111, 112 included in an electronic element cell 110 could be physically separated by an isolation structure (not shown), but the disclosure is not limited thereto.

In an embodiment, at least one of the electronic elements (e.g. the electronic element 111) is a sensor electronic element, as such, the electronic element cell 110 is referred as a sensor cell and/or the electronic device 100 is referred as an electronic sensor device. In an embodiment, a sensor cell including a plurality of sensor electronic elements may be referred as a sensor pixel, but the disclosure is not limited thereto. In an embodiment, the critical signal circuit 121 is electrically connected to the sensor electronic element (e.g. the electronic element 111) and the signal processing unit 150.

In an embodiment, the electronic element 111 (could be referred as a first electronic element) electrically connected to the critical signal circuit 121 is a sensor electronic element. At least one of the other electronic elements 112 (could be referred as a second electronic element) is another sensor electronic element. In an exemplary operating mode of the electronic device 100, signal from the electronic element 112 may be used to drive or trigger the electronic element 111 to send a signal, and/or drive or trigger the signal processing unit 150 to judge or determine the signal sent from the electronic element 111 through the critical signal circuit 121.

For example, the electronic element 111 electrically connected to the critical signal circuit 121 includes an IR (infrared) sensor electronic element, and other electronic elements 112 may include a visible light (e.g., red light, green light, or blue light) sensor electronic element. The photocurrent generated by the IR sensor electronic element increases with increasing of the corresponding irradiated photons. When the electronic device 100 is in a low visible light environment, the signal of the visible light sensor electronic element is judged or determined to be lower than a threshold by the signal processing unit 150. As such, the electronic element electrically connected to the critical signal circuit 121 could be enabled for sensing, and/or the signal processing unit 150 could be enabled for judging or determining the current value received from the electronic element 111 through the critical signal circuit 121. In an embodiment, the aforementioned electronic device 100 may be applied to an IR imaging apparatus (e.g., a night imaging apparatus), but the disclosure is not limited thereto.

For example, the electronic element 111 electrically connected to the critical signal circuit 121 includes a temperature sensor electronic element, and other electronic elements 112 may include electronic elements to drive or trigger the temperature sensor electronic element for sensing. The temperature sensor electronic element (the electronic element 111) could transmit electrical signals to the signal processing unit 150 through the critical signal circuit 121. The signal processing unit 150 could calculate or judge the ambient temperature of the temperature sensor electronic element by the received electrical signal (e.g., calculate the change of the voltage controlled oscillator (VCO) through the corresponding current value). In an embodiment, the aforementioned electronic device 100 may be applied to a temperature sensing electronic element or any type of chip with a temperature sensor electronic element integrated therein, but the disclosure is not limited thereto.

For example, the electronic element 111 electrically connected to the critical signal circuit 121 includes a specific light (e.g., laser) sensor electronic element, and other electronic elements 112 may include a motion (e.g., microelectromechanical systems (MEMS)) sensor electronic element. The photocurrent generated by the specific light sensor electronic element increases with increasing of the corresponding irradiated photons. A motion sensor electronic element could generate signals in a motion (e.g., moving or vibrating) state. When the electronic device 100 is in motion, the signal of the motion sensor electronic element is sent to the signal processing unit 150. As such, the electronic element electrically connected to the critical signal circuit 121 could be enabled for sensing, and/or the signal processing unit 150 could be enabled for judging or determining the current value sent thereto by the critical signal circuit 121. In an embodiment, the aforementioned electronic device 100 may be applied to a light detection and ranging (LiDAR) apparatus, but the disclosure is not limited thereto.

For example, the electronic element 111 electrically connected to the critical signal circuit 121 includes a specific molecular sensor electronic element, and other electronic elements 112 may include another molecular sensor electronic element or a fluid state (e.g., fluid pressure or fluid flow) sensor electronic element. The sensing current generated by the specific molecule sensor electronic element increases or decreases with increasing of the bonding number of corresponding specific molecules. Other molecule sensor electronic elements could generate or degenerate signals when other molecules are bonded. Fluid state sensor electronic elements could generate or degenerate signals due to fluid pressure or fluid flow. When the electronic device 100 is in a specific fluid environment, the signal of another molecular sensor electronic element or the fluid state sensor electronic element could trigger the electronic element electrically connected to the critical signal circuit 121 being enabled for sensing, and/or trigger the signal processing unit 150 being enabled for judging or determining the current value sent thereto by the critical signal circuit 121. In an embodiment, the aforementioned electronic device 100 may be applied to a molecular (e.g., biomolecule) sensing or gas (e.g., toxic gas) sensing apparatus, but the disclosure is not limited thereto.

It is worth noting that the abovementioned applications are only examples, and the disclosure is not limited thereto. Additionally, since the design (e.g., the structural design, for example, wider dimension) of the critical signal circuit 121 could make it have a lower overall resistance (comparing with other signal circuits 120), the accuracy and/or precise of the current signal transmitted by the critical signal circuit 121 could be improved. Moreover, since the transmission, judgment or determination of current signal (e.g., the signal transmitted by the critical signal circuit 121) with more accuracy and/or precision is optionally driven or triggered by signals (e.g., the signal transmitted by the other signal circuits 120) with less accuracy and/or precision, operation or power loading of the electronic device 100 could be reduced.

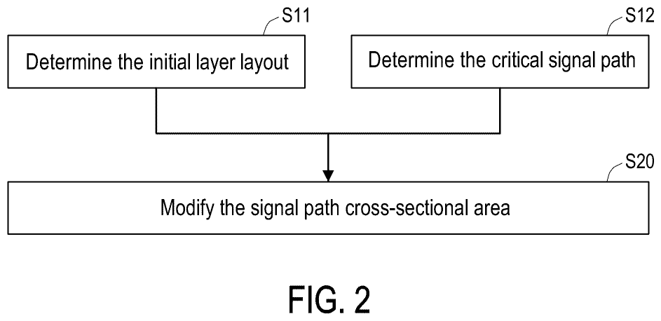

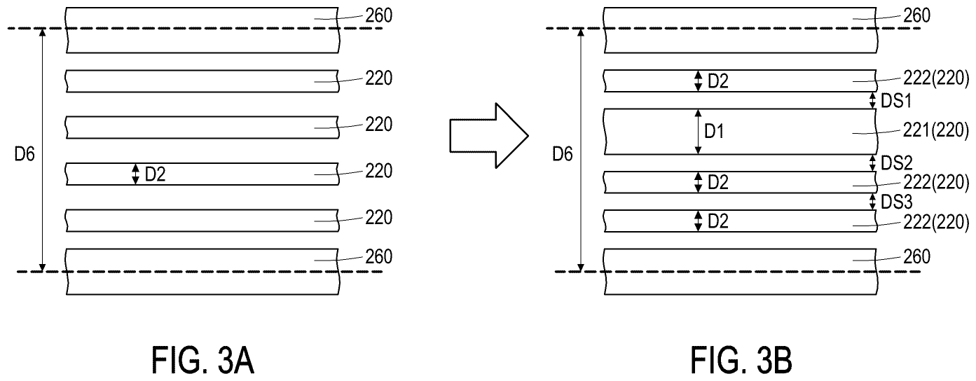

FIG. 2 illustrates a portion of a layout design flow of an embodiment of the disclosure. FIGS. 3A and 3B illustrate a portion of layout design diagrams of an embodiment of the disclosure. For example, FIG. 2 illustrates a layout design flow for an electronic device as shown in FIG. 1. For example, FIG. 2 illustrates a layout design flow optionally corresponding to the diagrams as shown in FIGS. 3A and 3B of the disclosure. For example, FIGS. 3A and 3B illustrate layout design diagrams optionally corresponding to the flow as shown in FIG. 2 of the disclosure.

As shown in FIG. 2, an example layout design flow including the following steps is provided. Determine the initial layer layout (e.g., the step S11) corresponding to conductive portions of each layer (e.g., M0 layer, M1 layer, M3 layer, M4 layer and so on, or V0 layer, V1 layer, V3 layer, V4 layer and so on) of an electronic device (e.g., an IC chip, or an electronic device the same or similar to the electronic device 100). Determine the critical signal path (e.g., the step S12) between a signal processing unit (e.g., the signal processing unit 150) and an electronic element (e.g., the electronic element 111). After determining the initial layer layout and the critical signal path, modify the initial layer layout to a modified layer layout by enlarging a physical cross-sectional area and/or an equivalent cross-sectional area of a corresponding circuit (e.g., a portion of the critical signal circuit 121) for the critical signal path.

In an embodiment, a layout (e.g., the abovementioned initial and/or modified layer layouts) is designed by an electronic design automation (EDA) software. The layout substantially corresponds to a distributed pattern of semiconductor portions (e.g., channels) of each layer, a distributed pattern of conductive portions (e.g., lines or vias) of each layer, a spaced pattern (e.g., trenches or holes) of one or more insulating or dielectric layers, and/or one or more corresponding photomask patterns used for forming the aforementioned patterns in a semiconductor manufacturing process. A layout (e.g., the abovementioned initial and/or modified layer layouts) basically need to be checked by an appropriate rule, for example, a design rule check (DRC) and/or a mask rule check (MRC). After that, the production of photomask and subsequent semiconductor manufacturing process will be performed.

For a detail description to the structure of the electronic device, only a portion of the top view distributed pattern of the conductive portion of a certain layer (e.g., M0 layer, M1 layer, M3 layer, M4 layer) is exemplarily shown in FIGS. 3A and 3B. It is worth noting that, for the sake of simplicity, the sizes or dimensions of the corresponding structures are labeled and described with the corresponding layout design drawings (e.g., FIGS. 3A and 3B).

Referring to FIG. 3A, the portion of the conductive portion of the certain layer constitutes two non-signal tracks 260 and a plurality signal tracks 220 therebetween. At least two of the signal tracks 220 are electrically connected to different electronic elements (e.g., different electronic elements of the electronic element cell 110 as shown in FIG. 1) respectively. Signal transmission is not performed pass through the two non-signal tracks 260 basically. The non-signal track 260 includes, for example, a power track 260, a grounding track 260, a shielding track 260, or a dummy track. The distance and/or the number of signal tracks 220 between two non-signal tracks 260 could be appropriately designed according to an appropriate design rule. Taking a semiconductor process for manufacturing an IC chip as an example, such design rule may be based on process or product reasons, such as but not limited to a process limit (e.g., an exposure limit, an etching limit, a deposition limit), improving process window, reducing defects, etc.

In an embodiment, for M0 layer, M1 layer, M3 layer, and/or M4 layer of an IC chip, the distance (center to center distance) D6 between two non-signal tracks 260 is 50 nanometers (nm)˜500 nm approximately.

In an embodiment, for M0 layer, M1 layer, M3 layer, and/or M4 layer of an IC chip, the number of signal tracks 220 between two non-signal tracks 260 is 3˜7, for example, four signal tracks 220 are shown in FIG. 3A.

In an embodiment, a physical width (e.g., a dimension of minor axis) D2 of the signal track 220 is greater than or substantially equal to 8 nm, for example, 8 nm˜100 nm approximately. In an embodiment, considering a semiconductor process for manufacturing an IC chip, the physical width corresponds or is referred as a critical dimension (CD).

In an embodiment, considering an electronic element (e.g., an electronic element of the electronic element cell 110 as shown in FIG. 1, or an electronic element formed using front-end of line (FEOL) fabrication techniques) which the signal track 220 is electrically connect thereto, a length (e.g., a dimension of major axis) of the signal track 220 is greater than or substantially equal to a contacted poly pitch (CPP) of the aforementioned electronic element. In an embodiment, a contacted poly pitch (CPP) of an electronic element is a sum of a gate length (Lg), a contact width (Wc), and two times of spacer thickness (2Tsp).

In an embodiment, for M0 layer, M1 layer, M3 layer, and/or M4 layer of an IC chip, the distance D6 between two non-signal tracks 260 is 6˜20 times of the width D2 (e.g., a dimension of minor axis) of the signal track 220.

In an embodiment, the pattern as shown in FIG. 3A corresponds to, for example, a portion of the initial layer layout of the step S11 as shown in FIG. 2.

Referring to FIGS. 3A and 3B, during the layout design stage, the cross-sectional area of at least one signal track 220 could be increased by, for example, increasing the physical width thereof. For example, a physical width D1 of the signal track 221 is wider a physical width D2 of one of the other signal tracks 220 (e.g., signal tracks 222). For example, as shown in FIGS. 1, 3A and 3B, a signal track 220 with a wider physical width (e.g., the signal track 221 as shown in FIG. 3B) corresponds to a portion of the critical signal circuit 121 for the critical signal path.

In an embodiment, the cross-sectional area of the signal track 221 is larger a cross-sectional area of any one of the signal tracks 222. In an embodiment, for M0 layer, M1 layer, M3 layer, and/or M4 layer of an IC chip, in all signal tracks 220 between two adjacent non-signal tracks 260, the signal track 221 for the critical signal path has a maximum cross-sectional area.

In an embodiment, the cross-sectional area of the signal track 221 is 1.1˜2.0 times the cross-sectional area of one of the signal tracks 222.

In an embodiment, the physical width D1 of the signal track 221 is wider a physical width D2 of any one of the signal tracks 222. In an embodiment, for M0 layer, M1 layer, M3 layer, and/or M4 layer of an IC chip, in all signal tracks 220 between two adjacent non-signal tracks 260, the signal track 221 for the critical signal path has a maximum width.

In an embodiment, the physical width D1 of the signal track 221 is 1.1˜2.0 times the physical width D2 of one of the signal tracks 220.

In an embodiment, the pattern as shown in FIG. 3B corresponds to, for example, a portion of the modified layer layout of the step S20 as shown in FIG. 2.

The pattern as shown in FIG. 3B must also follow a corresponding rule, for example, a design rule and/or a mask rule. For example, the distance D6 between two non-signal tracks 260 is 50 nanometers (nm)˜500 nm approximately, the number of signal tracks 220 between two non-signal tracks 260 is 3˜7, a physical width (e.g., the physical width D1 or the physical width D2) of the signal track 220 is greater than or substantially equal to 8 nm, and/or a length of the signal track 220 is greater than or substantially equal to a contacted poly pitch (CPP) of an electronic element which the signal track 220 is electrically connect thereto.

Referring to FIGS. 3A and 3B, during the stage of modifying the layout, the distance D6 between two non-signal tracks 260, a length of each of the signal tracks 220, and/or the number of signal tracks 220 between two non-signal tracks 260 may be unnecessary being changed or redesigned. As such, the steps of rule checking may be simplified, and/or the efficiency of layout design may be improved.

In an embodiment, in addition to increasing the physical width of the signal track 220, a space distance between adjacent signal tracks 220 is further equidistant optionally. As such, the process window may be improved, and/or defects may be reduced. For example, the space distance DS1, the space distance DS2, and the space distance DS3 are substantially the same.

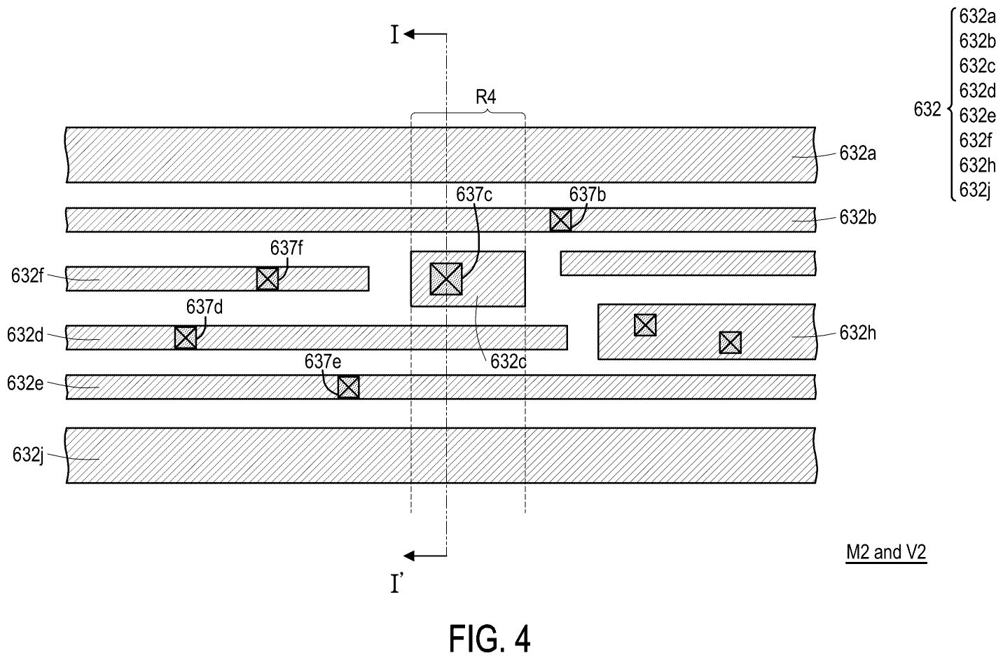

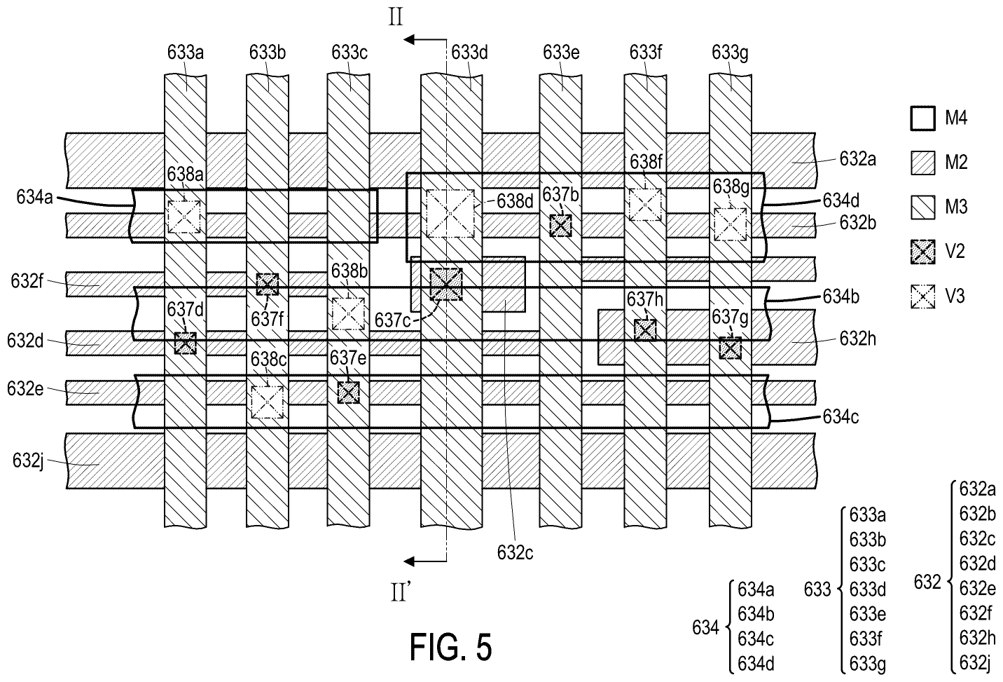

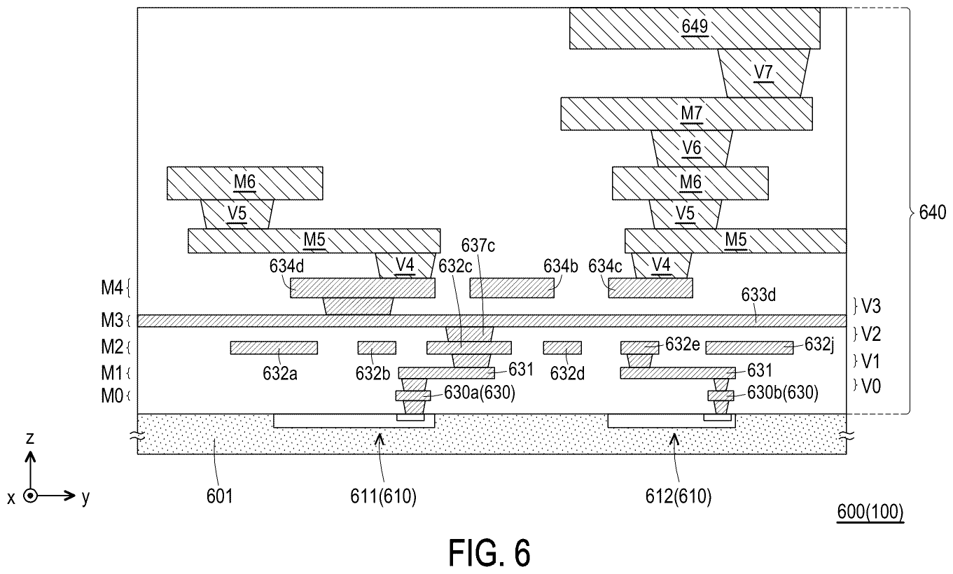

FIG. 4 illustrates a top view of a portion of an electronic device of an embodiment of the disclosure. FIG. 5 illustrates a top view of a portion of an electronic device of an embodiment of the disclosure. FIG. 6 illustrates a cross-sectional view of a portion of an electronic device of an embodiment of the disclosure. For example, FIG. 4 illustrates a top view of a portion of M2 layer and V2 layer optionally shown in FIG. 6. For example, FIG. 5 illustrates a top view of a portion of M2 layer, V2 layer, M3 layer, V3 layer, and M4 layer optionally shown in FIG. 6. FIG. 6 illustrates a cross-sectional view of a portion of an electronic device 100 optionally corresponding to I-I′ line shown in FIG. 4 or II-II′ line as shown in FIG. 5. In an embodiment, the electronic device 100 as shown in FIGS. 4, 5, and/or 6 is an IC chip 600.

In addition, in FIGS. 4, 5 and 6 or other similar drawings, the form of the conductive portions (e.g., tracks and/or vias) is shown as an example. For example, even though two tracks in two adjacent interconnect layers are not connected in the cross section shown in FIG. 6, they may still be connected in other cross-sections not shown. A corresponding portion of the interconnect layers or via layers may form a portion of a corresponding circuit. In addition, the layout design of the above circuit may be adjusted according to design requirements, which is not limited in the disclosure.

Referring to FIGS. 4, 5, and 6, the IC chip 600 may include a semiconductor substrate 601, one or more electronic elements (e.g., a sensor electronic element, an active electronic element (e.g., a transistor), and/or a passive electronic element (e.g., a resistor, a capacitor, or an inductance)) 610, and interconnect structure 640. The electronic element 610 may be formed using front-end of line (FEOL) fabrication techniques. The interconnect structure 640 may be formed using back-end of line (BEOL) fabrication techniques and may be electrically coupled to a corresponding electronic element 610. The electronic element 610 and/or the interconnect structure 640 are exemplary shown in FIG. 6, the formations or types of the electronic element 610 and/or the interconnect structure 640 are not limited in the disclosure.

In an embodiment, the IC chip 600 is a sensor chip, but the disclosure is not limited thereto.

In an embodiment, the IC chip 600 is a functional chip with a sensor electronic element (one implemental example of the electronic element 610) integrated therein. The aforementioned functional chip may be a dynamic random access memory (DRAM) chip, a static random access memory (SRAM) IC chip or a high bandwidth memory (HBM) chip, an application-specific integrated circuit (ASIC) chip, an application processor (AP) chip, a system on chip (SoC) IC chip or a high performance computing (HPC) chip, but the disclosure is not limited thereto.

The interconnect structure 640 may include a plurality interconnect layers (e.g., an M0 layer, an M1 layer, . . . or an Mi layer). Each interconnect layer may include corresponding tracks. That is, tracks of each interconnect layer are at the same level and have substantially the same material and/or structure (e.g., thickness). Corresponding tracks in adjacent interconnect layers extend in different directions. For example, tracks (e.g., tracks 131, 132, 133 as shown in FIGS. 4 and 5) in the M2 or M4 layer extend along the x-direction, and tracks in the M3 layer extend along the y-direction. Corresponding tracks in adjacent interconnect layers are electrically connected through corresponding electrically conductive vias in the via layer (e.g., a V0 layer, a V1 layer, a V2 layer, . . . or a Vi−1 layer) therebetween. A material of the M0 layer, the V0 layer, and/or the M1 layer may include Copper (Cu), Cobalt(Co), Ruthenium (Ru), Molybdenum (Mo), Chromium (Cr), Tungsten (W), Manganese (Mn), Rhodium (Rh), Iridium (Ir), Nickel (Ni), Palladium (Pd), Platinum (Pt), Silver (Ag), Gold (Au), Aluminum (Al), Tantalum (Ta), Titanium (Ti) or other metal nitride (e.g., titanium nitride (TiN), tantalum nitride (TaN)). A thickness of the M0 layer, the V0 layer, the M1 layer, the V1 layer, the M2 layer, the V2 layer, the M3 layer, the V3 layer, and/or the M4 layer may about 50 Å to 1000 Å.

The topmost interconnect layer (e.g., the electrically conductive layer 649 as shown in FIG. 6) in the interconnect structure 640 may include a plurality of IC chip pads. The IC chip pad may be a signal pad (e.g., an I/O pad) or a ground pad. A corresponding track in the bottommost interconnect layer (e.g., the M0 layer) in the interconnect structure 640 is electrically connected a corresponding region of the electronic element (e.g., the source S, the drain D, or the gate G, but the disclosure is not limited thereto) by one or more electrical conductors (e.g., corresponding electrically conductive vias).

Additionally, for simplicity of illustration, corresponding dielectric or insulating layers (e.g., the dielectric layers 120, 140, 164) are omitted or simply illustrated in the FIGS. 4, 5 and 6.

In an embodiment, the electronic element 611 and another electronic element (e.g., the electronic element 612) constitute an electronic element cell (e.g., the electronic element cell 110 as shown in FIG. 1). The electronic element 611 and the electronic element 612 are electrically connected to a signal processing unit (e.g., the signal processing unit 150 as shown in FIG. 1) by corresponding signal circuits (e.g., signal circuits 120 as shown in FIG. 1) respectively. Comparing with other signal circuits (e.g., a signal circuit electrically connected to the electronic element 612), the signal circuit electrically connected to the electronic element 611 has a lower resistance value. In an embodiment, a portion of a circuit diagram of the IC chip 600 is exemplarily shown in FIG. 1.

In an embodiment, comparing with other signal circuits (e.g., a signal circuit electrically connected to the electronic element 612), the signal circuit electrically connected to the electronic element 611 has a higher cross-sectional area.

In an IC chip, a critical dimension of the conductive portion of each layer may decrease with closing to the semiconductor substrate. For example, the physical width (a dimension along the y-axis) of each tracks 630 of the M0 layer is narrower than the physical width (a dimension along the x-axis) of each tracks 631 of the M1 layer, the physical width of each tracks 631 of the M1 layer is narrower than the physical width (a dimension along the y-axis) of each tracks 632 of the M2 layer, the physical width of each tracks 632 of the M2 layer is narrower than the physical width (a dimension along the x-axis) of each tracks 633 of the M3 layer, the physical width of each tracks 633 of the M3 layer is narrower than the physical width (a dimension along the y-axis) of each tracks 634 of the M4 layer, and so on. Moreover, the interconnect layers (e.g., the M5 layer, the M6 layer, the M7 layer, and so on) far away from the substrate may not have a significant impact on the overall resistance due to have sufficient physical width. As such, for the IC chip 600, adopting the abovementioned layout design flow as shown in FIG. 2 for the M0, M1, M2, M3, and/or M4 layers and/or forming the tracks of the M0, M1, M2, M3, and/or M4 layers corresponding to the abovementioned structure as shown in FIG. 3B could improve the efficiency of layout design, and/or quality of the IC chip. For example, the pattern of a portion of tracks of an interconnect layers (e.g., the region R4 of the M4 layer) corresponds to the pattern as shown in FIG. 3B. That is, considering the IC chip (one implemental example of an electronic device) 600 as shown in FIG. 6 with one or more layer as shown in FIGS. 4 and 5, a circuit diagram as shown in FIG. 1, a layout design flow as shown in FIG. 2, and/or a layout diagram as shown in FIG. 3B could be further considered.

Referring to FIGS. 3B and 4-6, the track 632a, the track 632b, the track 632c, the track 632d, the track 632e, and the track 632j correspond to the non-signal track 260, the signal track 220, the signal track 220, the signal track 220, the signal track 220, and the non-signal track 260 respectively. That is, the signal track 632c could be a portion of the critical signal circuit 121 for the critical signal path having a wider physical width than the signal track 632b, the signal track 632d, and the signal track 632e.

In an embodiment, the via 637c landing on the track 632c having a wider physical dimension than other vias landing on other tracks (e.g., the via 637b landing on the track 632b, the via 637d landing on the track 632d, and/or the via 637e landing on the track 632e).

In an embodiment, in the M0, M1, M2, M3, and/or M4 layers, a track of the aforementioned layer for being a portion of the critical signal circuit has a wider physical width than other tracks.

For example, as shown in FIG. 5, in the M3 layer, the track 633d for being a portion of the critical signal circuit having a wider physical width than other tracks 633a, 633b, 633c, 633e. The track 633d is electrically connected to the track 632c by the via 637c. The track 633a is electrically connected to the track 632d by the via 637d. The track 633b is electrically connected to the track 632f by the via 637f. The track 633c is electrically connected to the track 632e by the via 637e. The track 633e is electrically connected to the track 632b by the via 637b.

For example, as shown in FIG. 5, in the M4 layer, the track 634d for being a portion of the critical signal circuit having a wider physical width than other tracks 634a, 634b, 634c. The track 634d is electrically connected to the track 633d by the via 638d. The track 634a is electrically connected to the track 633a by the via 638a. The track 634b is electrically connected to the track 633c by the via 638b. The track 634c is electrically connected to the track 633b by the via 638c.

For example, as shown in FIG. 5, in the M0 layer, the track 630a for being a portion of the critical signal circuit having a wider physical width than other tracks 630b.

In an embodiment, the critical signal path includes parallel current paths. For example, as shown in FIG. 5, the track 634d is electrically connected to the track 633f and track 633g by the via 638f and the via 638g respectively, and the track 632h is electrically connected to the track 633f and track 633g by the via 637h and the via 637g respectively.

In an embodiment, the vias 637g, 637h landing on the same track 632h having a wider physical width than other tracks (e.g., the tracks 632b, 632d, 632e) are misaligned. For example, the connecting line of centers of the vias 637g, 637h is neither parallel nor perpendicular to the long axis of the track. As such, a process window for forming the vias may be improved. For example, a shortest distance between the via 637g and an edge of the track 632h is different from a shortest distance between the via 637h and the edge of the track 632h.

In an embodiment, the vias 638f, 638g are electrically connected to the same track 634d having a wider physical width than other tracks (e.g., the tracks 634a, 634b, 634c) are misaligned.

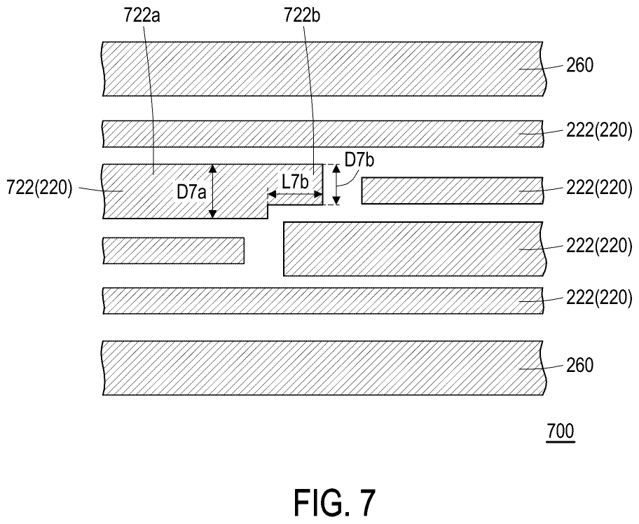

FIG. 7 illustrates a top view of a portion of another electronic device of an embodiment of the disclosure.

In an embodiment, a physical width of a signal track 722 is inconsistent. For example, as shown in FIG. 7, in the direction along the long axis of the signal track 220, the signal track 722 includes a major portion 722a and an extension portion 722b extending therefrom. A physical width D7a of the major portion 722a is wider than a physical width D7b of the extension portion 722b.

In an embodiment, a physical width of the signal track 722 (e.g., the physical width D7a of the major portion 722a and/or the physical width D7b of the extension portion 722b) is greater than or substantially equal to 8 nm, for example, 8 nm˜100 nm.

In an embodiment, considering an electronic element which the signal track 722 is electrically connect thereto, a length of each portion of the signal track 220 is greater than or substantially equal to a contacted poly pitch (CPP) of the aforementioned electronic element. For example, the physical length L7b of the extension portion 722b is greater than or substantially equal to a contacted poly pitch (CPP).

In accordance with some embodiments of the present disclosure, an electronic device includes a first electronic element, a second electronic element, a first signal track, and a second signal track. The second electronic element is different from the first electronic element. The first signal track is electrically connected to the first electronic element. The second signal track is electrically connected to the second electronic element and electrically separated from the first signal track. A width of the second signal track is substantially 8˜100 nm. The first signal track has a larger cross-sectional area than the second signal track. In an embodiment, the first signal track and the second signal track are at a same level. In an embodiment, the first signal track and the second signal track comprise a same material and have substantially a same thickness. In an embodiment, a width of the first signal track is greater than a width the second signal track. In an embodiment, the width of the first signal track is approximately 1.1 to 2 times the width of the second signal track. In an embodiment, the electronic device further includes two non-signal tracks, wherein the first signal track and the second signal track are disposed between the two non-signal tracks. In an embodiment, lengths of the first signal track and the second signal track are greater than or substantially equal to a contacted poly pitch of the first electronic element. In an embodiment, the first signal track comprises a major portion and an extension portion extending therefrom, wherein a width of the major portion is wider than a width of the extension portion.

In accordance with some embodiments of the present disclosure, an electronic device includes a semiconductor substrate, a back-end-of-line (BEOL) structure, and a first electronic element. The BEOL structure includes a plurality of interconnect layers disposed on the semiconductor substrate. The first electronic element is disposed between the semiconductor substrate and the BEOL structure. One of the interconnect layers is a first interconnect layer comprising a first signal track and a second signal track, the first signal track is electrically connected to the first electronic element, and the second signal track is electrically separated from the first signal track. A width of the first signal track is wider than a width the second signal track. In an embodiment, less than five of other interconnect layers different form the first interconnect layer is/are disposed between the semiconductor substrate and the first interconnect layer. In an embodiment, other interconnect layers different form the first interconnect layer comprises a second interconnect layer, and wherein the second interconnect layer comprises a third signal track and a fourth signal track, the third signal track is electrically connected to the first signal track, and the fourth signal track is electrically connected to the second signal track; and a width of the third signal track is wider than a width the fourth signal track. In an embodiment, the first track and the second track have a first extension direction; the third track and the fourth track have a second extension direction; and the first extension direction is substantially perpendicular to the second extension direction. In an embodiment, the BEOL structure further comprises a via layer disposed between the first interconnect layers and the second interconnect layer, wherein: the via layer comprises a first via and a second via, the first via is disposed between and electrically connected to the first signal track and the third signal track, and the second via is disposed between and electrically connected to the second signal track and the fourth signal track; and a dimension of the first via is larger than a dimension of the second via. In an embodiment, the BEOL structure further comprises a via layer disposed on the first interconnect layer, wherein: the via layer comprises a first via and a second via disposed on and electrically connected to the first signal track; and the first via and the second via are structurally separated. In an embodiment, a shortest distance between the first via and an edge of the first signal track is different from a shortest distance between the second via and the edge of the first signal track. In an embodiment, other interconnect layers different form the first interconnect layer comprises a second interconnect layer, and wherein: the second interconnect layer comprises a plurality of third signal tracks and a fourth signal track; the plurality of third signal tracks are electrically connected to the first signal track; and the fourth signal track is electrically connected to the second signal track.

In accordance with some embodiments of the present disclosure, an electronic device includes a signal processing unit, an electronic element cell, a first signal circuit, and a second signal circuit. The electronic element cell includes a first electronic element and a second electronic element. The second electronic element is different form the first electronic element. The first signal circuit is electrically connected to the first electronic element and the signal processing unit. The second signal circuit is electrically connected to the second electronic element and the signal processing unit, and electrically separated from the first signal circuit. A resistance value of the first signal circuit is lower than a resistance value of the second signal circuit. In an embodiment, an analog signal transmission is performed through the first signal circuit between the first electronic element and the signal processing unit. In an embodiment, the first electronic element is a sensor electronic element. In an embodiment, the first electronic element is driven or triggered by the second electronic element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a first electronic element;
a second electronic element, different from the first electronic element;
a first signal track, electrically connected to the first electronic element; and
a second signal track, electrically connected to the second electronic element and electrically separated from the first signal track, wherein:
a width of the second signal track is substantially 8˜100 nm; and
the first signal track has a larger cross-sectional area than the second signal track.

2. The electronic device of claim 1, wherein the first signal track and the second signal track are at a same level.

3. The electronic device of claim 1, wherein the first signal track and the second signal track comprise a same material and have substantially a same thickness.

4. The electronic device of claim 1, wherein a width of the first signal track is greater than a width the second signal track.

5. The electronic device of claim 4, wherein the width of the first signal track is approximately 1.1 to 2 times the width of the second signal track.

6. The electronic device of claim 1, further comprising:
two non-signal tracks, wherein the first signal track and the second signal track are disposed between the two non-signal tracks.

7. The electronic device of claim 1, wherein lengths of the first signal track and the second signal track are greater than or substantially equal to a contacted poly pitch of the first electronic element.

8. The electronic device of claim 1, wherein the first signal track comprises a major portion and an extension portion extending therefrom, wherein a width of the major portion is wider than a width of the extension portion.

9. An electronic device, comprising:
a semiconductor substrate;
a back-end-of-line (BEOL) structure, comprising a plurality of interconnect layers disposed on the semiconductor substrate; and
a first electronic element, disposed between the semiconductor substrate and the BEOL structure, wherein:
one of the interconnect layers is a first interconnect layer comprising a first signal track and a second signal track, the first signal track is electrically connected to the first electronic element, and the second signal track is electrically separated from the first signal track; and
a width of the first signal track is wider than a width the second signal track.

10. The electronic device of claim 9, wherein less than five of other interconnect layers different form the first interconnect layer are disposed between the semiconductor substrate and the first interconnect layer.

11. The electronic device of claim 9, wherein other interconnect layers different form the first interconnect layer comprises a second interconnect layer, and wherein:
the second interconnect layer comprises a third signal track and a fourth signal track, the third signal track is electrically connected to the first signal track, and the fourth signal track is electrically connected to the second signal track; and
a width of the third signal track is wider than a width the fourth signal track.

12. The electronic device of claim 11, wherein:
the first track and the second track have a first extension direction;
the third track and the fourth track have a second extension direction; and
the first extension direction is substantially perpendicular to the second extension direction.

13. The electronic device of claim 11, wherein the BEOL structure further comprises a via layer disposed between the first interconnect layers and the second interconnect layer, wherein:
the via layer comprises a first via and a second via, the first via is disposed between and electrically connected to the first signal track and the third signal track, and the second via is disposed between and electrically connected to the second signal track and the fourth signal track; and
a dimension of the first via is larger than a dimension of the second via.

14. The electronic device of claim 9, wherein the BEOL structure further comprises a via layer disposed on the first interconnect layer, wherein:
the via layer comprises a first via and a second via disposed on and electrically connected to the first signal track; and
the first via and the second via are structurally separated.

15. The electronic device of claim 14, wherein a shortest distance between the first via and an edge of the first signal track is different from a shortest distance between the second via and the edge of the first signal track.

16. The electronic device of claim 9, wherein other interconnect layers different form the first interconnect layer comprises a second interconnect layer, and wherein:
the second interconnect layer comprises a plurality of third signal tracks and a fourth signal track;
the plurality of third signal tracks are electrically connected to the first signal track; and
the fourth signal track is electrically connected to the second signal track.

17. An electronic device, comprising:
a signal processing unit;
an electronic element cell, comprising
a first electronic element; and
a second electronic element, different form the first electronic element;
a first signal circuit, electrically connected to the first electronic element and the signal processing unit; and
a second signal circuit, electrically connected to the second electronic element and the signal processing unit, and electrically separated from the first signal circuit, wherein:
a resistance value of the first signal circuit is lower than a resistance value of the second signal circuit.

18. The electronic device of claim 17, wherein an analog signal transmission is performed through the first signal circuit between the first electronic element and the signal processing unit.

19. The electronic device of claim 18, wherein the first electronic element is a sensor electronic element.

20. The electronic device of claim 17, wherein the signal processing unit or the first electronic element is driven or triggered by the second electronic element.
